(19) United States
(12) Patent Application Publication
(10) Pub. No.: US 2020/0411416 A1
(43) Pub. Date: Dec. 31, 2020

(54) METHOD OF MAKING A SEMICONDUCTOR PACKAGE HAVING PROJECTIONS

(71) Applicant: TEXAS INSTRUMENTS INCORPORATED, Dallas, TX (US)

(72) Inventors: Sreenivasan K. Koduri, Allen, TX (US); Sylvester Ankamah-Kusi, Dallas, TX (US)

(21) Appl. No.: 16/455,095

(22) Filed: Jun. 27, 2019

(51) Int. Cl. H01L 23/495; H01L 21/48; H01L 21/56; H01L 23/31

(52) U.S. Cl. CPC H01L 23/4951; H01L 21/4825; H01L 23/49548; H01L 21/565; H01L 23/3114; H01L 21/4828

(57) ABSTRACT

A method of making a semiconductor package includes providing a base made from a conductive material. A surface of the base is covered with an outer layer of material different from the conductive material. Gaps are formed in the outer layer. The base is etched through the gaps to form projections on the base extending along a centerline to an end surface. Each projection has a first width at the end surface and a second width at the base less than the first width. The outer layer is removed. Leads and a die pad are formed from the base with the projections extending from the leads and the die pad. A die is attached to the projections. An insulating layer is provided over the leads, the die, and the die pad.

### SUMMARY

In one example, a method of making a semiconductor package includes providing a base made from a conductive material. A surface of the base is covered with an outer layer of material different from the conductive material. Gaps are formed in the outer layer. The base is etched through the gaps to form projections on the base extending along a centerline to an end surface. Each projection has a first width at the end surface and a second width at the base less than the first width. The outer layer is removed. Leads and a die pad are formed from the base with the projections extending from the leads and the die pad. A die is attached to the projections. An insulating layer is provided over the leads, the die, and the die pad.

In another example, a semiconductor package includes a base extending in a plane and having opposing first and second surfaces. Projections extend from the first surface and along a centerline out of the plane. Each projection includes a sidewall and an end surface for receiving solder. Each projection has a first width perpendicular to the centerline at the end surface and a second width at the first surface less than the first width. A die is provided having posts for receiving the solder on the respective projections to couple the die to the base. An electrically insulating layer extends over the die and the base.

Other objects and advantages and a fuller understanding of the invention will be had from the following detailed description and the accompanying drawings.

### BRIEF DESCRIPTION OF THE DRAWINGS

FIG. 1 is a schematic view of an example lead frame.

FIG. 2A is an enlarged view of a portion of the lead frame of FIG. 1.

FIG. 2B is a side view of FIG. 2A.

FIG. 3 is a section view of a die for use with the lead frame of FIG. 1.

FIG. 4 is a side view of the die connected to the lead frame.

FIGS. 5A-5E are schematic illustrations of an example method of forming the lead frame.

FIGS. 6A-6E are schematic illustrations of another example method of forming the lead frame.

### DETAILED DESCRIPTION

Lead frames can be used in various packaging applications, including flip-Chip packages that use relatively high power densities. In some instances, the lead frame is attached to the die directly rather than using traditional bond wires. This configuration can help reduce the parasitic resistance and inductance of the package. Due to the direct connection between the die and lead frame, it is desirable to maintain thermal performance in the package.

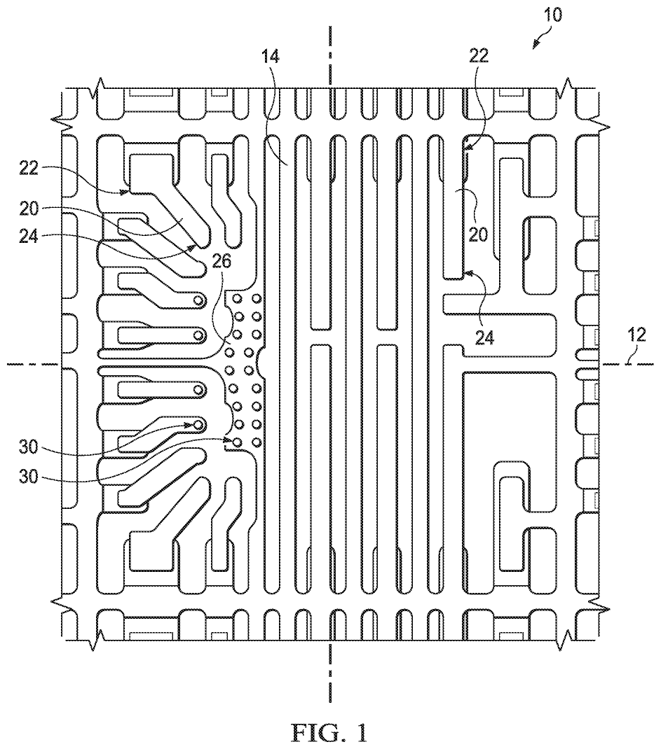

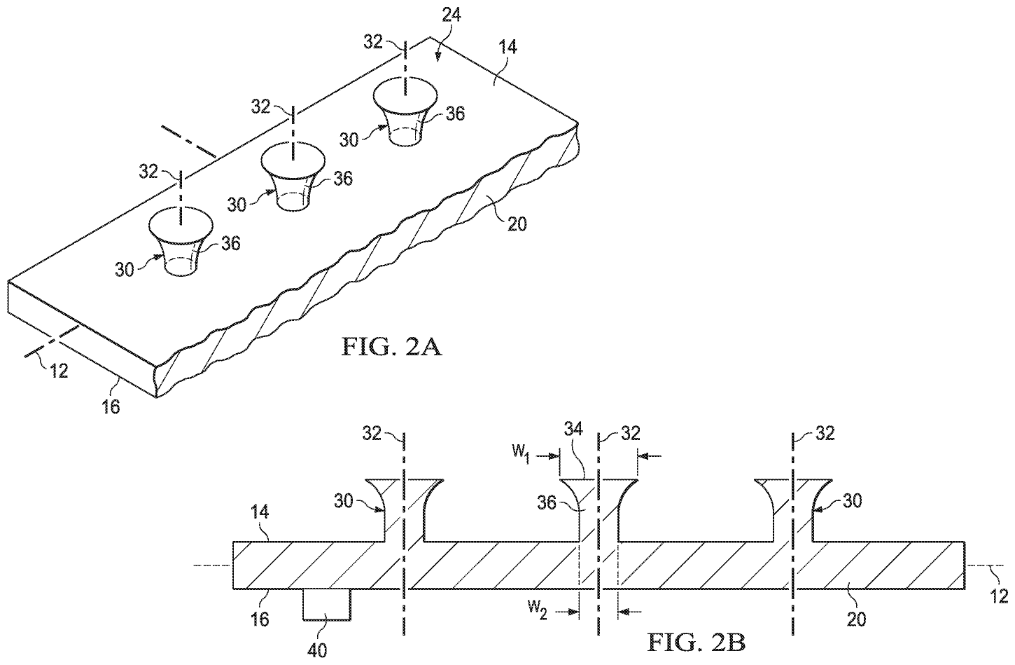

FIG. 1 illustrates an example lead frame or base 10 for improving thermal performance in semiconductor packaging. The lead frame 10 is formed from a conductive material, such as copper, and extends within a plane 12. The lead frame 10 includes a first surface 14 and a second surface 16 (see FIG. 2) opposing the first surface. The lead frame 10 further includes leads 20. Each lead 20 extends from a first end 22 located at the outer periphery [or dam bar] of the lead frame 10 to a second end 24 located closer to the geometric center of the lead frame. The lead frame 10 further includes at least one die pad 26. As shown, the die pad 26 is located adjacent the second ends 24 of the leads 20.

Referring to FIGS. 2A-2B, projections 30 extend from the first surface 14 of lead frame 10. In one example, the projections 30 extend from the second ends 24 of the leads 20 and out of the plane 12. Alternatively or additionally, the projections 30 extend from the die pads 26. The projections 30 are integrally formed with the leads 20 and/or die pads 26 and extend along a centerline 32 away from the first surface 14. Each projection 30 includes an axial end surface 34 and a sidewall 36. The end surface 34 can be centered on the centerline 32 or offset therefrom (not shown). That said, the end surface 34 can be coaxial/aligned with the interface between the projection 30 and the first surface 14 or offset therefrom. In one example, the sidewall 36 is curved, e.g., concave. Alternatively, the side wall 36 can be tapered (not shown).

The projection 30 has a first width w₁ at the end surface 34 and a second width w₂ less than the first width at the first surface 14, i.e., adjacent the lead frame 10. The width of the projection 30 can decrease continuously between the end surface 34 and the first surface 14. Alternatively, no portion of the projection 30 is wider than the remainder of the projection above it. In any case, each projection 30 can have a length along the centerline 32 of about 15 μm to about 100 μm.

At least one sink 40 is provided on the second surface 16 of the lead frame 10 and is associated with one or more of the projections 30. As shown, one sink 40 is secured to the second surface 16 and is associated with three projections 30. The sink 40 is offset from the projections 30, i.e., left of all three centerlines 32 as shown. Consequently, each projection 30 is spaced successively further from the sink 40 in the left-to-right direction shown. The sink 40 is ultimately coupled to a printed circuit board (PCB) or other structures (not shown) to which the lead frame 10 is connected for supplying power thereto.

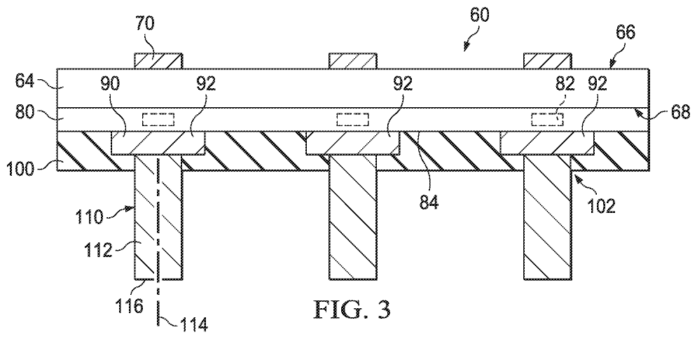

Referring to FIG. 3, a die 60 is provided for connecting to the lead frame 10. As shown, the die 60 includes a substrate 64 having a first side 66 and a second side 68. One or more sources 70 are connected to the first side 66. The substrate 64 can be circular, square or rectangular. The substrate 64 can be formed from a semiconductor material, such as silicon.

Integrated circuits 80 are fabricated or otherwise provided on the second side 68 of the substrate 64. The integrated circuits 80 include one or more contacts shown schematically at 82. The integrated circuits 80 can be arranged in a grid or array equidistantly spaced from one another about the second side 68. Depending on the sizes of the substrate 64 and integrated circuits 80, thousands or tens of thousands of integrated circuits can be fabricated on the second side 68 of the substrate. Each integrated circuit 80 includes a surface or side 84 facing away from the substrate 64.

A layer 90 of electrically conductive material is provided on the side 84 of the integrated circuits 80 and defines one or more electrically conductive elements 92 for redistributing and/or routing power. The layer 90 can be formed from a metal, such as copper or aluminum. The elements 92 can include electrically conductive lines and/or electrically conductive contacts formed in different patterns.

A layer 100 of material extends over the layer 90 and covers the entire side 84 of the integrated circuit 80. The layer 100 is formed from an electrically insulating material, such as polyimide. One or more slots or openings 102 extend entirely through the insulating layer 100 to expose portions of the layer 90, namely, to expose portions of the elements 92. The openings 102 can be sized and shaped to expose different portions of the same element 92 or portions of different elements. Each opening 102 can have a constant cross-sectional area or a cross-sectional area that varies along its depth (not shown). It will be appreciated that the layer 100—and therefore the openings 102 therein—can be omitted (not shown).

An electrically conductive interconnect 110 extends through each opening 102 (when present) into contact with the exposed portions of the elements 92. Each interconnect 110 includes a post 112 formed from a conductive material, such as copper. The post 112 extends along a centerline 114 to an axial end surface 116. The post 112 can have a circular axial cross-section with a diameter of about 40 μm to about 350 μm. The post 112 can have a length along the centerline 114 of about 30 μm to about 75 μm. The interconnect 110 can be formed by electroplating the post 112 directly onto the insulating layer 100 and through the openings 102 into contact with the elements 92.

The interconnect 110 completely fills each opening 102 and the shape of the interconnect is therefore defined by the shape of the opening. That said, configuring an opening 102 to expose particular portions of the elements 92 readily enables the interconnect 110 extending into the opening to contact those exposed portions. The interconnects 110 associated with a single integrated circuit 80 can have different sizes and/or different shapes from one another.

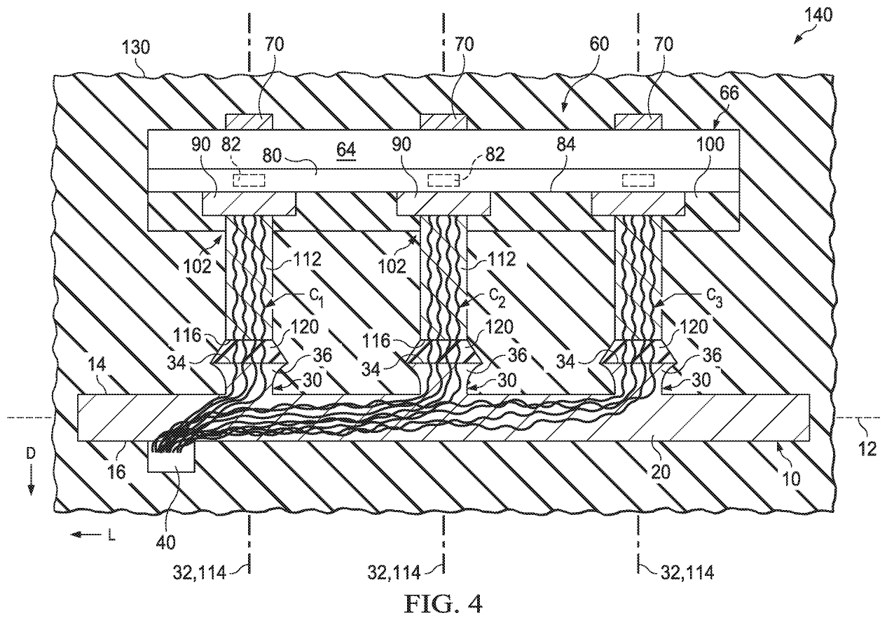

Referring to FIG. 4, to secure the die 60 to the lead frame 10, the posts 112 are aligned with corresponding projections 30 such that respective centerlines 32, 114 are aligned with one another. The posts 112 are then connected to the projections 30 via solder 120 positioned between and engaging the axial end surfaces 34, 116.

The solder 120 can be formed from a conductive material such as tin, e.g., SnAg or NiSnAg, that undergoes reflow under heat to secure the die 60 to the projections 30 on the lead frame 10. The solder 120 can have a thickness between the axial end surfaces 34, 116 of about 10 μm to about 30 μm. As shown, the solder 120 has a substantially trapezoidal shape that widens in a direction extending towards the projection 30. In any case, the solder 120 mechanically and electrically connects the die 60 to the lead frame 10. That said, in the example shown connecting the die 60 to the lead frame 10 couples three current sources 70 on the die 60 to a single current sink 40 on the lead frame.

Once all the dies 60 are secured to the lead frame 10, a layer 130 of an electrically insulating material is overmolded over the dies and leadframe to form a semiconductor package 140. The semiconductor package 140 can be, for example, a power supply, a laptop or server component or any component for a semiconductor package capable of routing power from multiple sources to a single sink.

In operation, currents represented by C₁, C₂, and C₃, respectively, originate at the sources 70 and passes through the integrated circuit 80 to the contacts 82, which transfer the current to the posts 112. The currents C₁, C₂, and C₃ travel in the direction D (downward as shown) through each post 112 generally along or parallel to the centerline 114 to the lead frame 10. The currents C₁, C₂, and C₃ are collected and distributed by the lead frame 10 to the same sink 40 connected to the second surface 16.

More specifically, the currents C₁, C₂, and C₃ passing in the direction D through each post 112 flows through the associated solder 120 and projection 30 into the lead frame 10. Current C₁ from the post 112 closest to the sink 40 (the leftmost post shown) moves substantially vertically to reach the sink but also experience some lateral movement in the direction L through the lead frame 10. Currents C₂, C₃ from the posts 112 spaced further from the sink 40 (the center and rightmost post shown) move a greater distance laterally in the direction L through the lead frame 10 to the sink 40. The lead frame 10 therefore helps accumulate and direct multiple currents C₁-C₃ to the same sink 40, which increases the current intensity and density through the package 140. As a result, the current is non-uniformly distributed across the lead frame 10 and across the solder 120 even when each post 112 has the same amount of current sources.

Current prefers to flow through the path of least resistance, e.g., the shortest path. That said, the lead frame 10 described herein is advantageous in that it controls the current flow path in a manner that reduces crowding at the interface between the solder 120 and the post 112 and relocates the location of current crowding to within the lead frame. To this end, the shape of the projections 30 is such that the shortest—and therefore most favorable—current path is at/parallel to the centerline 32 of the projection 30 whereas the longest current path is at the periphery/sidewall 36.

The post-solder 112, 120 interface has weak electromigration properties and can thereby fail at a much faster rate. Consequently, current crowding at the post-solder 112, 120 interface can reduce the lifespan of the connection by creating thermal and current hot spots and/or causing intermetallic growth, e.g., migration of the solder into the post resulting in the production of Cu₃Sn and Cu₆Sn₅. Intermetallic growth can lead to voids in the post 112 and/or in the solder 120 and ultimately can lead to consumption/decay of the post.

The lifespan of the post-solder interface is governed by Black's Equation:

MTTF=(A/jⁿ)e^{(Q/kT)}, where

MTTF is the mathematical model for mean time to failure

A is a constant

j is the current density

n is a model parameter

Q is the activation energy

k is Boltzmann's constant; and

T is the absolute temperature in K

From the above equation, an increase in current density (j) results in a decrease in potential life of the interface. Along with current density (j), there will also be temperature increase and, thus, a hot spot at the same location. This local heating can also impact the electromigration lifespan.

With this in mind, the projections 30 provided on the lead frame 10 advantageously shape the landing area of the currents C₁-C₃ at the lead frame, resulting in a preferred path for current flow through the center of each post 112. In particular, the projections 30 direct current C₁-C₃ flow at and along the centerline 114 along substantially the entire length of the post 112. As a result, the currents C₁-C₃ substantially occupy the middle portion of each post 112—instead of spreading to the periphery adjacent the projection-solder 30, 120 interface—and thereby reduce current crowding and related high current density at the projection-solder interface.

Instead, the configuration of the projection 30 moves the higher current density to the interface between the projection 30 and the first surface 14 of the lead frame 10. Since the first surface 14 and projection 30 are formed from the same conductive material, this interface is much more robust than the post-solder 30, 120 interface and can tolerate electromigration failures to a much higher rate. That said, the projection-first surface 14, 30 interface is better suited to withstand current crowding as the paths of the currents C₁-C₃ angle towards the sidewalls 36 in the direction of the sink 40. As a result, the lifespan and reliability of the semiconductor package 140 can be increased.

For the sake of comparison, the current density at a conventional post-solder interface with a current of 6 A at each source can be on the order of about 3.03e8 A/m² whereas the current density at the post-solder interface with the projection 30 described herein can be on the order of about 1.85e8 A/m² to about 2.3e8 A/m². This variance is attributed to the varying lateral distance L between each projection 30 and the sink 40.

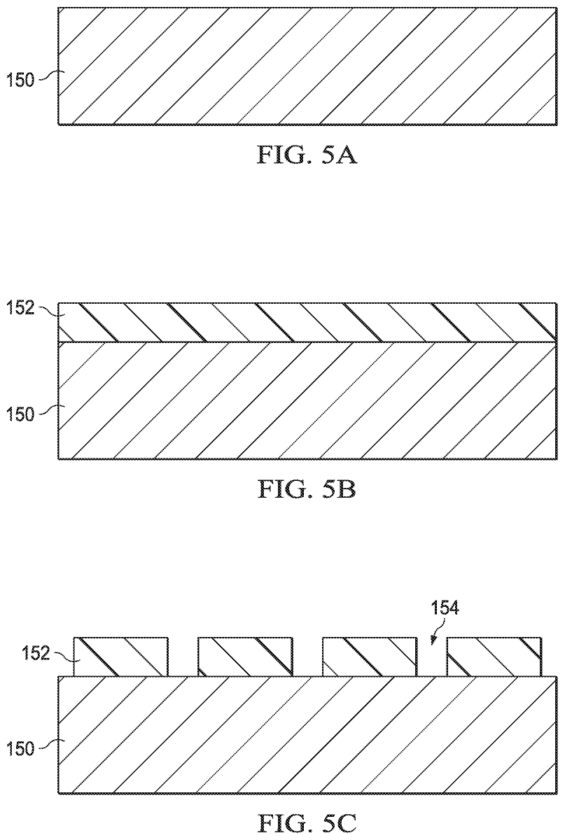

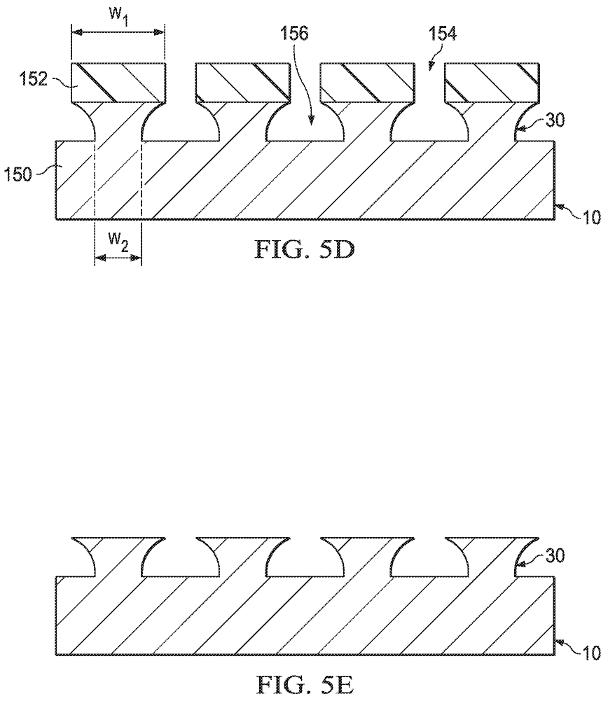

FIGS. 5A-5E illustrate a method of making the lead frame shown and described herein. In FIG. 5A, a base metal 150 for the lead frame 10 is provided in planar form. A photo resistant outer layer 152 is applied to the top side of the base 150 (FIG. 5B). The outer surface of the composite structure is masked, exposed to light, and developed with a solvent, which forms gaps 154 in the photo resistant layer 152 (FIG. 5C).

The base 150 is then etched through the gaps 154 in the photo resistant layer 152 to form cavities 156 in the base, which define the projections 30 (FIG. 5D). In one example, the etching is performed using a diluted acid or other liquid that dissolves the base 150 in an isotropic manner. The remaining photo resistant layer 152 is then stripped from the base 150, e.g., by an organic stripper, inorganic stripper or dry stripping, leaving behind the lead frame 10 with integrally formed projections 30 shown in FIG. 5E.

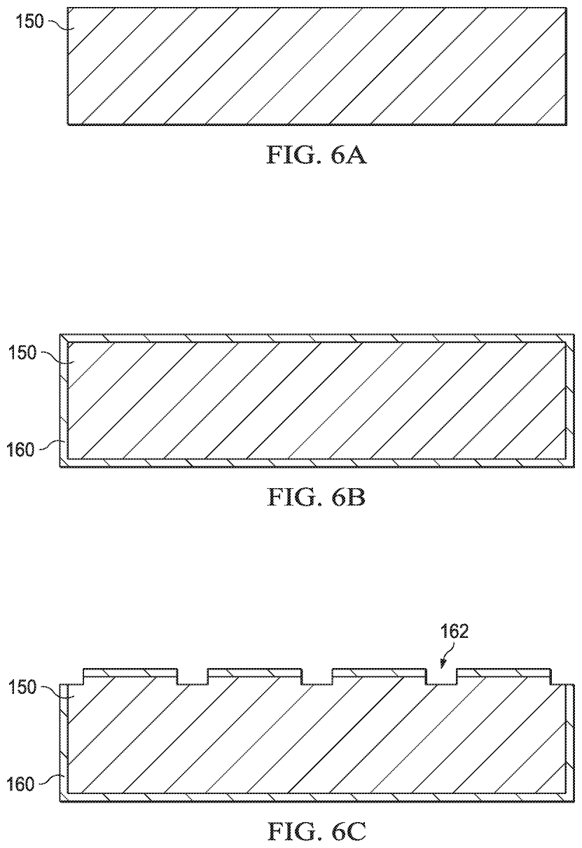

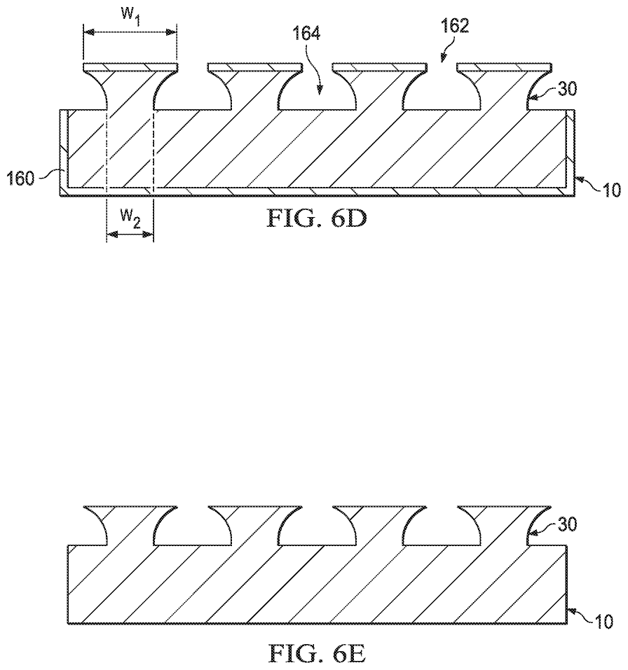

In another example shown in FIGS. 6A-6E, the base metal 150 for the lead frame 10 is provided in planar form (FIG. 6A). An outer layer 160 of, for example, NiPdAu is plated over the base 150 (FIG. 6B). Grooves or gaps 162 are cut in the layer 160 by laser, plasma, chemical, etc. (FIG. 6C). Alternatively, the layer 160 is selectively plated over the base 150 to form the gaps 162 (not shown).

In any case, the base 150 is then etched through the gaps 162 in the layer 160 to form cavities 164 in the base 150, which define the projections 30 (FIG. 6D). The remaining photo resistant layer 152 is then stripped from the base 150, e.g., by an organic stripper, inorganic stripper or dry stripping, leaving behind the lead frame 10 with integrally formed projections 30 (FIG. 6E). Precisely etching the cavities 164 through the gaps 162 allows the projections 30 to be spaced closer to one another, e.g., on the order of about 90 μm apart, compared to existing interconnects.

With both methods, once the projections 30 are made the rest of the lead frame 10, e.g., the leads 20 and the die pad(s) 26, is formed from the base 150 to produce, for example, the lead frame shown in FIG. 1. More specifically, the leads 20 and die pad(s) 26 are formed such that the projections 30 extend therefrom. Defining the lead frame 10 from the base 150 can be accomplished by stamping, etching, etc.

Each die 60 is then secured to the projections 30 as previously described. The insulating layer 130 is overmolded over/around each electronic package 140. If multiple electronic packages 140 are formed on the same lead frame 10, the overmolded lead frame is singulated to separate the electronic packages from one another.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. To this end, it will also be appreciated that features shown and illustrated in any one example can likewise be added to/interchanged with features in any other example.

We claim:

1. A method of making a semiconductor package, comprising the steps of:
providing a base made from a conductive material;
covering a surface of the base with an outer layer of material different from the conductive material;
forming gaps in the outer layer;
etching the base through the gaps to form projections on the base extending along a centerline to an end surface, each projection having a first width at the end surface and a second width at the base less than the first width;
removing the outer layer;
forming leads and a die pad from the base with the projections extending from the leads and the die pad;
attaching a die to the projections; and
providing an insulating layer over the leads, the die, and the die pad.

2. The method recited in claim 1, wherein the step of covering a surface of the base comprises plating the outer layer onto the surface of the base.

3. The method recited in claim 2, wherein the outer layer comprises NiPdAu.

4. The method recited in claim 2, wherein the step of forming gaps in the outer layer comprises cutting gaps in the outer layer.

5. The method recited in claim 1, wherein the step of covering a surface of the base comprises coating a photoresist onto the surface of the base.

6. The method recited in claim 5, wherein the step of forming gaps in the outer layer comprises:
masking the outer surface;
exposing the outer surface to light; and
developing the outer surface with a solvent.

7. The method recited in claim 5, wherein the outer layer comprises NiPdAu.

8. The method recited in claim 5, wherein the step of etching the base comprises exposing the base to acid through the gaps in the outer layer.

9. The method recited in claim 1, wherein a sidewall of each projection is curved between the end surface and the base.

10. The method recited in claim 1, wherein each projection has a length along a centerline of about 15μ to 100 μm.

11. A semiconductor package comprising:
a base extending in a plane and having opposing first and second surfaces, projections extending from the first surface and along a centerline out of the plane, each projection including a sidewall and an end surface for receiving solder, each projection having a first width perpendicular to the centerline at the end surface and a second width at the first surface less than the first width;
a die having posts for receiving the solder on the respective projections to couple the die to the base;
an electrically insulating layer extending over the die and the base.

12. The semiconductor package recited in claim 11, wherein the sidewall is curved.

13. The semiconductor package recited in claim 12, wherein curved sidewall extends directly from the first surface.

14. The semiconductor package recited in claim 11, wherein the sidewall is concave.

15. The semiconductor package recited in claim 11, wherein the end surface of at least one projection is centered on the centerline.

16. The semiconductor package recited in claim 11, wherein the end surface of at least one projection is offset from the centerline.

17. The semiconductor package recited in claim 11, wherein the width decreases continuously from the first width to the second width.

18. The semiconductor package recited in claim 11, wherein the end surface extends parallel to the plane.

19. The semiconductor package recited in claim 11, wherein the projections are spaced laterally from one another along the first surface such that current flows laterally through the lead frame.

20. The semiconductor package recited in claim 11, further comprising a sink secured to the second surface of the lead frame.

21. The semiconductor package recited in claim 20, wherein multiple of the projections direct current to the sink.

22. The semiconductor package recited in claim 11, wherein each projection has a length along a centerline of about 15 μm to 100 μm.

23. The semiconductor package recited in claim 11, wherein each post has a length along a centerline of about 30 μm to 75 μm.

24. The semiconductor package recited in claim 11, wherein each post has a circular axial cross-section with a diameter of about 40 μm to 350 μm.

25. The semiconductor package recited in claim 11, wherein the solder between the end surface of each projection and a corresponding post has a thickness of about 10 μm to 30 μm.

26. The semiconductor package recited in claim 11, wherein the solder between the end surface of each projection and a corresponding post has a trapezoidal shape that widens in a direction extending towards the projection.
